(19) United States
(12) Patent Application Publication
(10) Pub. No.: US 2001/0016372 A1
(43) Pub. Date: Aug. 23, 2001

(54) Mounting method and apparatus of bare chips

(75) Inventor: Tomoo Murakami, Tokyo (JP)

Correspondence Address: OSTROLENK FABER GERB & SOFFEN, 1180 AVENUE OF THE AMERICAS, NEW YORK, NY, 100368403

(73) Assignee: NEC Corporation

(21) Appl. No.: 09/785,965

(22) Filed: Feb. 16, 2001

(30) Foreign Application Priority Data
Feb. 22, 2000 (JP) 044692/2000

(51) Int. Cl. H01L 21/44

(52) U.S. Cl. 438/113

(57) ABSTRACT

A mounting method and apparatus of bare chips to a mounting substrate, in which the bare chips can be mounted on the mounting substrate automatically and in a low cost, is provided. In particular, a mounting method and apparatus of bare chips to a mounting substrate, in which plural bare chips having various sizes are effectively mounted on the mounting substrate, is provided. At this mounting method of the bare chips to the mounting substrate, in which the bump electrodes of each of the bare chips are connected to pads of the mounting substrate electrically via a resin film put between the bare chip and the mounting substrate, hardening contraction strength of the resin film is utilized. First, the bump electrodes of plural bare chips are formed on a wafer at the same time. And a resin film is adhered tentatively on the surface where the bump electrodes were formed on the wafer by such as a vacuum laminating method. After this, the wafer is divided into each of the plural bare chips having the resin film by dicing. And each of the plural bare chips having the resin film is mounted on the mounting substrate. And the bump electrodes of each of the plural bare chips are connected to the pads of the mounting substrate electrically by applying heat and pressure. With this, compared with a conventional method, in which the bump electrodes of each of the bare chips are formed and a resin film whose size is equivalent to the size of each of the bare chips is supplied at the time when each of the bare chips is mounted on the mounting substrate, a large amount of the mounting cost is reduced at the present invention.

### BACKGROUND OF THE INVENTION

The present invention relates to a mounting method and apparatus of bare chips of such as an LSI on a mounting substrate.

### DESCRIPTION OF THE RELATED ART

Recently, a structure, in which bare chips are mounted in high density on a mounting substrate, has been simplified, corresponding to that electronic equipment has been light, thin, and small sized. And there is a flip chip bonding method, as a high density mounting structure for bare chips having this simplified structure.

And various kinds of flip chip bonding methods have been proposed and realized. For example, there is a method in which bump electrodes formed on a bare chip are electrically bonded to pads being electrodes of a mounting substrate by using a bonding material such as solder, or by using contraction strength of resin existing in a position between the bare chip and the mounting substrate.

As mentioned above, for the current mounting pitch level, various methods have been put to practical use, however when the electronic equipment is made to be lighter, thinner, and smaller sized, the bonding pitch is required to be a finer pitch. For example, at a fine bonding region in which the bonding pitch is less than 80 μm, when the method using the bonding material mentioned above is used, it becomes impossible to supply the bonding material on the mounting substrate. And further, when the bump electrodes are formed on the bare chips by applying a wire bonding method, there is a limit for forming its pitch. Consequently, it becomes impossible to apply the bonding method mentioned above at the fine bonding.

As one of the bonding methods, which are practical for this fine bonding, there is a bonding method using a resin film. And there are two kinds of existing bonding methods using the resin film. One is a bonding method using an anisotropic conductive film (ACF), hereinafter referred to as an ACF method, and the other is a bonding method using a non-conductive film (NCF), hereinafter referred to as a NCF method.

The ACF is a film in which conductive particles are dispersed in binder resin. FIGS. 1A, 1B, and 1C are sectional views showing mounting processes of a bare chip on a mounting substrate at a conventional ACF method. Referring to FIGS. 1A to 1C, this conventional ACF method is explained. As shown in FIG. 1A, a bare chip 100 provides bump electrodes 200. An ACF 300 is put between the bare chip 100 having the bump electrodes 200 and a mounting substrate 400 as shown in FIG. 1B. And the binder resin in the ACF 300 is melted by applying heat and pressure, and the conductive particles dispersed in the ACF 300 are captured at the position between the bump electrodes 200 of the bare chip 100 and pads 500 of the mounting substrate 400. With this, the bare chip 100 and the mounting substrate 400 are connected electrically. At the position where the bump electrodes 200 of the bare chip 100 and the pads 500 of the mounting substrate 400 do not exist, the conductive particles not captured are filled in, however, these not captured conductive particles are isolated one another, therefore the insulation is secured. At the same time, the bare chip 100 and the mounting substrate 400 are bonded mechanically by the binder resin of the ACF 300, and the bonded part is sealed as shown in FIG. 1C.

At the ACF method mentioned above, the conductive particles in the ACF 300 are needed to put the position between the bump electrodes 200 of the bare chip 100 and the pads 500 of the mounting substrate 400. Therefore, the bump electrodes 200 and the pads 500 are desirable to be flat. Consequently, the bump electrodes 200 of the bare chip 100 are not needed to be a protruded type bump electrode, and can be formed by plating. Therefore, the ACF method has an advantage for the fine processing.

The NCF is a film that liquid insulation resin is formed to be a film type and does not contain conductive particles. Mounting processes at the NCF method are almost equivalent to the processes at the ACF method. And the NCF is adhered on the region mounting a bare chip on a mounting substrate, and bump electrodes formed on the bare chip penetrate the NCF and contact with pads of the mounting substrate by applied pressure, and the bare chip and the mounting substrate are connected electrically.

At the NCF method, the contraction strength generated by hardening of the resin keeps the connection of the bare chip and the mounting substrate, and differing from the ACF method, the conductive particles are not contained in the NCF. Therefore, the bump electrodes of the bare chip directly contact with the pads of the mounting substrate. The bump electrodes formed on the bare chip need to penetrate the NCF, therefore the bump electrodes are desirable to be a protruded type bump electrode being a ball shape, not being a flat type bump electrode formed by plating.

However, there are problems at the conventional bonding methods used the resin film mentioned above, that is, the conventional bonding methods cause a high cost. First, when various sizes of bare chips are mounted on a mounting substrate, plural sizes of resin films are needed to supply on the mounting substrate, corresponding to the various sizes of the bare chips.

In this case, a mounting apparatus, in which plural resin films having various sizes are supplied to a mounting substrate, is impossible to be produced. Because, there is a problem that handling mechanically plural small sized resin films is impossible, and further a problem that positioning exactly plural resin films having various sizes on the mounting substrate by deciding the mounting positions is impossible. Actually, the resin films are not mounted on the mounting substrate by automated mechanical operation, and generally mounted by manual operation. Consequently, many operators are required at the mounting operation, and this causes a high cost.

Second, at the case that the ACF method is used, the ACF is a high price and can not be used abundantly. Generally, when the plural resin films having various sizes are formed, the plural resin films are cut to meet the sizes of the bare chips. However, the remaining resin films after cut become waste, and the resin films are not used effectively.

### SUMMARY OF THE INVENTION

It is therefore an object of the present invention to provide a mounting method and apparatus of bare chips to a mounting substrate, in which the bare chips can be mounted on the mounting substrate automatically and in a low cost. In particular, a mounting method and apparatus of bare chips to a mounting substrate, in which plural bare chips having various sizes are effectively mounted on the mounting substrate, is provided.

According to the present invention, there is provided a mounting method of bare chips to a mounting substrate. At this mounting method of the bare chips to the mounting substrate, in which the bump electrodes of each of the bare chips are connected to pads of the mounting substrate electrically via a resin film put between the bare chip and the mounting substrate, hardening contraction strength of the resin film is utilized. First, the bump electrodes of plural bare chips are formed on a wafer at the same time. And a resin film is adhered tentatively on the surface where the bump electrodes were formed on the wafer by such as a vacuum laminating method. After this, the wafer is divided into each of the plural bare chips having the resin film by dicing. And each of the plural bare chips having the resin film is mounted on the mounting substrate. And the bump electrodes of each of the plural bare chips are connected to the pads of the mounting substrate electrically by applying heat and pressure. With this, compared with a conventional method, in which the bump electrodes of each of the bare chips are formed and a resin film whose size is equivalent to the size of each of the bare chips is supplied at the time when each of the bare chips is mounted on the mounting substrate, a large amount of the mounting cost is reduced at the present invention.

According to the present invention, there is provided a mounting apparatus of bare chips to a mounting substrate, in which bump electrodes of each of the bare chips are connected electrically to pads of the mounting substrate via a resin film put between each of the bare chips and the mounting substrate. The mounting apparatus of bare chips to the mounting substrate provides bump forming equipment for forming bump electrodes of plural bare chips formed on a wafer at the same time, resin film adhering equipment for tentatively adhering the resin film on the surface, where the bump electrodes of the plural bare chips were formed, of the wafer, dicing equipment for dividing the wafer into each of the plural bare chips having the resin film, and mounting equipment for mounting the each of the plural bare chips having the resin film on the mounting substrate and for connecting the bump electrodes of each of the plural bare chips to the pads of the mounting substrate by applying heat and pressure.

### BRIEF DESCRIPTION OF THE DRAWINGS

The objects and features of the present invention will become more apparent from the consideration of the following detailed description taken in conjunction with the accompanying drawings in which:

FIGS. 1A, 1B, and 1C are sectional views showing mounting processes of a bare chip on a mounting substrate at a conventional ACF method;

FIG. 2 is a sectional view showing a first structure mounted a bare chip on a mounting substrate by a first mounting method of the present invention;

FIG. 3 is a sectional view showing a second structure mounted a bare chip on a mounting substrate by a second mounting method of the present invention;

FIG. 4A is a perspective view of a wafer composed of bare chips using at the mounting method of the present invention;

FIGS. 4B and 4C are sectional views showing processes forming bare chips at the mounting method of the present invention;

FIGS. 5A, 5B, 5C, and 5D are sectional views showing processes of the mounting method of a bare chip of the present invention;

FIG. 6 is a block diagram showing a mounting apparatus to realize the mounting method of bare chips of the present invention;

FIG. 7 is a sectional view of the resin film 3 using at the mounting apparatus of the present invention;

FIG. 8 is a sectional view showing a first structure of a resin film tentative adhering instrument in resin film adhering equipment of the mounting apparatus of the present invention;

FIG. 9 is a sectional view showing a second structure of a resin film tentative adhering instrument in the resin film adhering equipment of the mounting apparatus of the present invention;

FIG. 10 is a sectional view showing a structure of dicing equipment in the mounting apparatus of the present invention; and

FIGS. 11A to 11E are sectional views showing processes at the second structure of the mounting method of the present invention shown in FIG. 3.

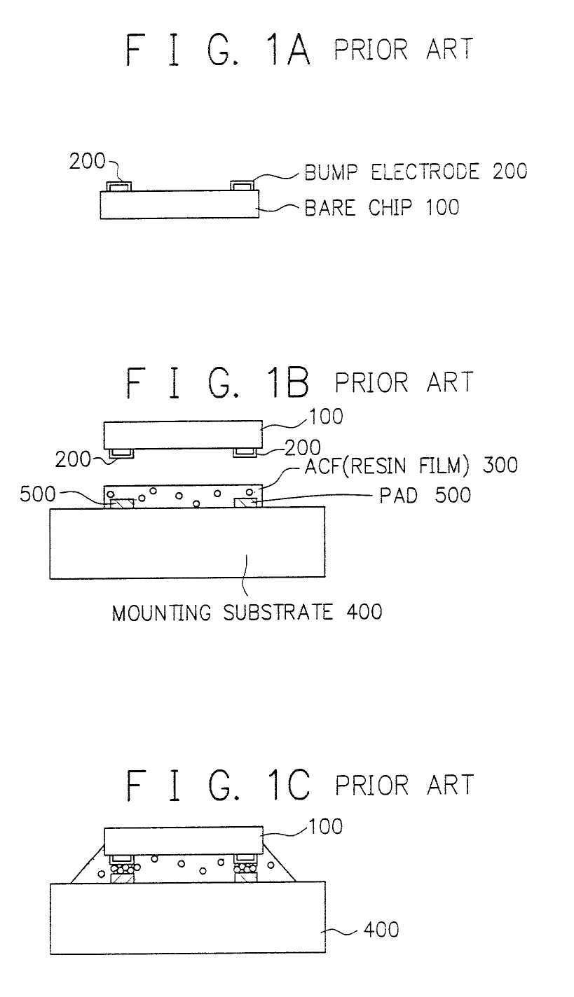

### DESCRIPTION OF THE PREFERRED EMBODIMENTS

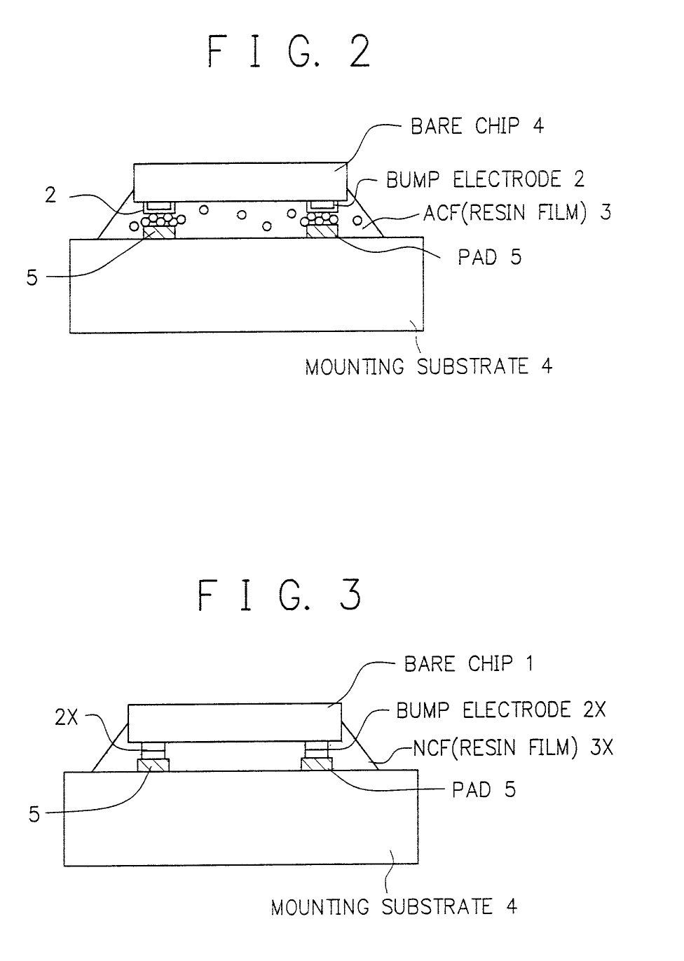

Referring now to the drawings, embodiments of the present invention are explained in detail. FIG. 2 is a sectional view showing a first structure mounted a bare chip on a mounting substrate by a first mounting method of the present invention. FIG. 3 is a sectional view showing a second structure mounted a bare chip on a mounting substrate by a second mounting method of the present invention. The structures shown in FIGS. 2 and 3 are equivalent to the conventional structure from the viewpoint of their appearances.

That is, as shown in FIG. 2, at the first structure of the present invention, a bare chip 1 having bump electrodes 2 being a flat surface is used, and the bare chip 1 is mounted on a mounting substrate 4 by putting an ACF 3 containing conductive particles between the bare chip 1 and the mounting substrate 4. The bump electrodes 2 of the bare chip 1 are connected to pads 5 of the mounting substrate 4 with the conductive particles in the ACF 3. As the conductive particles in the ACF 3, nickel (Ni) particles plated gold (Au), or resin particles plated Ni and Au is used.

And at the second structure of the present invention, as shown in FIG. 3, a bare chip 1 having bump electrodes 2X being a protruded surface is used, and the bare chip 1 is mounted on a mounting substrate 4 by putting an NCF 3X not containing conductive particles between the bare chip 1 and the mounting substrate 4. The bump electrodes 2X of the bare chip 1 are directly connected to pads 5 of the mounting substrate 4.

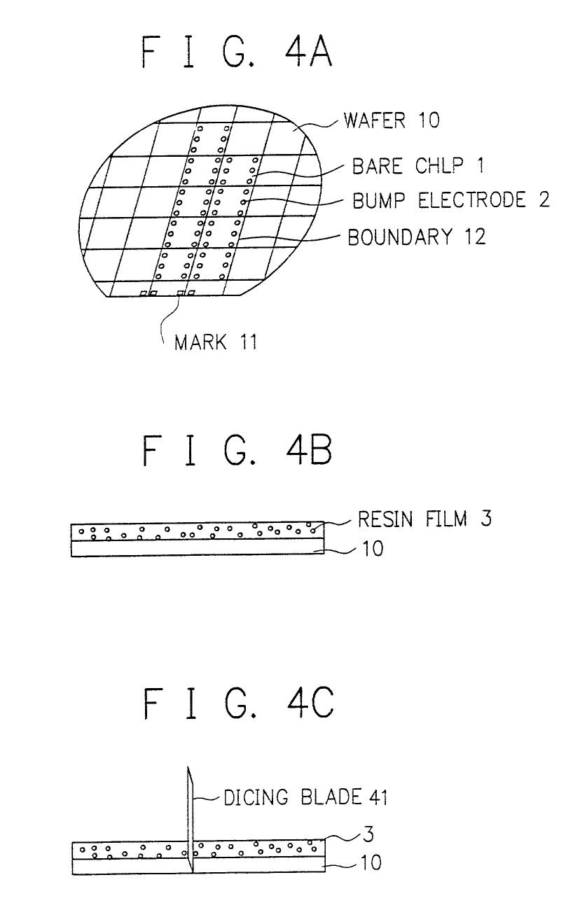

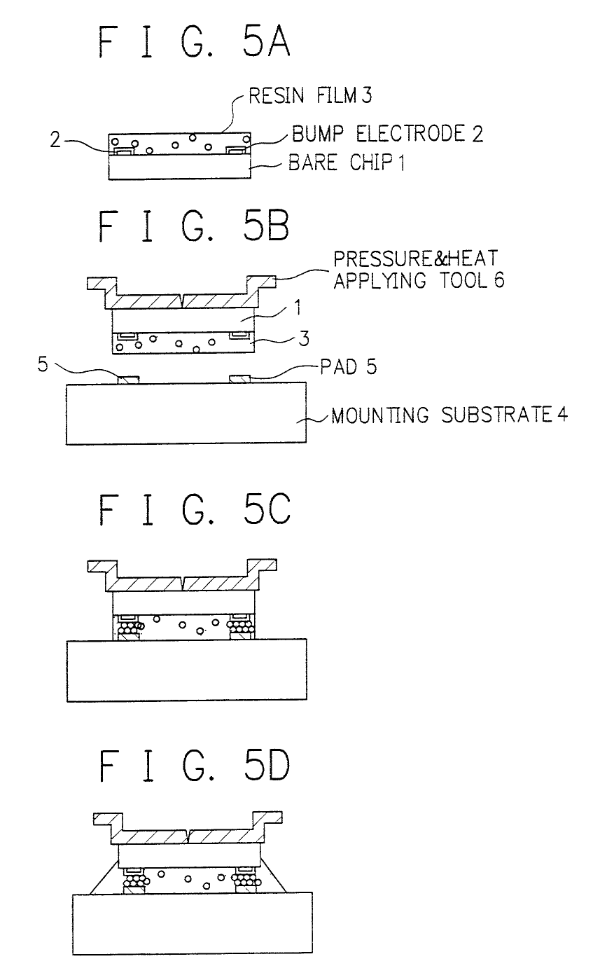

Next, referring to drawings, mounting methods of a bare chip on a mounting substrate of the present invention are explained. FIG. 4A is a perspective view of a wafer composed of bare chips using at the mounting method of the present invention. FIGS. 4B and 4C are sectional views showing processes forming bare chips at the mounting method of the present invention. And FIGS. 5A, 5B, 5C, and 5D are sectional views showing processes of the mounting method of a bare chip of the present invention.

As shown in FIG. 4A, bump electrodes 2 are formed on the surface of a wafer 10 in which plural bare chips 1 were formed at the same time. In this case, plural bare chips 1 in the wafer 10 are all the same.

At the wafer 10, boundaries 12 among the plural bare chips 1 are not visible like lines, however, the positions of the boundaries 12 can be confirmed by detecting marks 11 formed in the wafer 10. And the boundaries 12 correspond to cutting lines of the wafer 10, when the wafer 10 is divided into each of the bare chips 1 later.

The bump electrodes 2 are formed on the wafer 10 at the same time by an existing method such as an electroless plating method. In this case, a resist film is formed at the part where the bump electrodes 2 are not formed, and a metal plating layer is formed at the part not existing the resist film. And after formed the bump electrodes 2, the resist film is removed.

The material of the bump electrodes 2 is not limited but conductive. For example, a material, which Au is plated on Ni, can be used as the bump electrodes 2. The height of the bump electrodes 2 is not also limited severely, but in this case, the height is 20 μm.

The bump electrodes 2 can be also made of a metal layer formed by a vapor deposition method but not by a plating method. The forming method of the bump electrodes 2 is not limited to the methods mentioned above.

Next, as shown in FIG. 4B, a resin film 3 is tentatively adhered to the whole surface of the wafer 10. The kind of resin film is not limited, however, in this case, an existing ACF is used. And this resin film 3 is a thermo-hardening type film, and its hardening contraction coefficient is larger than its thermal expansion coefficient. And the thickness of the resin film 3 is larger than the height of the bump electrodes 2 formed on the wafer 10, and in this case, the thickness is 30 μm.

When the resin film 3 is tentatively adhered to the whole surface of the wafer 10, it is desirable that this is executed in reduced atmospheric pressure. By making the atmosphere thin, forming bubbles between the wafer 10 and the resin film 3 is prevented. And further when a low temperature, by which the resin film 3 is not melted, is tentatively applied, the adhering strength is made to be strong, and this is further desirable.

As shown in FIG. 4C, by dicing the wafer 10 along the boundaries 12 shown in FIG. 4A by using a dicing blade 41, each of the bare chips 1 having the resin film 3 is separated.

Next, as shown in FIG. 5A, the bare chip 1 having the resin film 3 is formed by the dicing process shown in FIG. 4C. And after this, as shown in FIG. 5B, the bare chip 1 having the resin film 3 is held by a pressure and heat applying tool 6. And the bare chip 1 having the resin film 3 is positioned in a state that the bump electrodes 2 of the bare chip 1 and the pads 5 of the mounting substrate 4 face each other.

After finished the positioning, as shown in FIG. 5C, the pressure and heat applying tool 6 is moved downward, and the resin film 3 is contacted with the mounting substrate 4. After this, as shown in FIG. 5D, the resin film 3 is melted and hardened by the pressure and heat applied to the bare chip 1 by the pressure and heat applying tool 6. That is, the bump electrodes 2 of the bare chip 1 are connected to the pads 5 of the mounting substrate 4 in a state that the conductive particles are put between the bump electrodes 2 and the pads 5, by the pressure applied after the resin film 3 contacted with the surface of the mounting substrate 4. At this state, the resin film 3 is liquidized by applying heat, and voids are removed, and also a fillet is formed at the surrounding part of the bare chip 1. And the first structure shown in FIG. 2 is completed.

At the case that plural bare chips being different sizes are mounted on a mounting substrate, first, each of plural bare chips being different sizes having resin films of different sizes is formed by the processes shown in FIGS. 4A to 4C. And after this, each of the plural bare chips is mounted on the mounting substrate by positioning each of the bare chips and by applying pressure and heat as shown in FIGS. 5B to 5D.

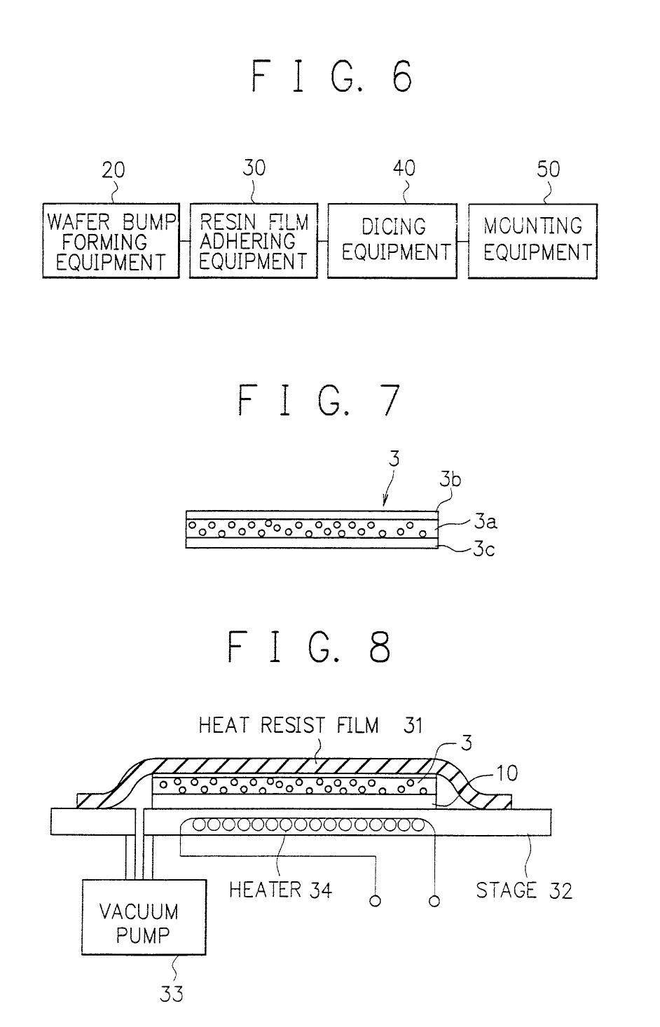

FIG. 6 is a block diagram showing a mounting apparatus to realize the mounting method of bare chips of the present invention. In FIG. 6, carrying equipment and transfer robots, which carries or transfers wafers, bare chips, and mounting substrates, are needed between each of equipment composed the mounting apparatus, but are not shown.

The mounting apparatus for mounting bare chips on a mounting substrate consists of wafer bump forming equipment 20, resin film adhering equipment 30, dicing equipment 40, and mounting equipment 50.

The wafer bump forming equipment 20 forms the bump electrodes 2 on the wafer 10 at the same time as shown in FIG. 4A. Therefore, at the embodiment of the present invention, the wafer bump forming equipment 20 provides an electroless plating unit or a vapor deposition unit for forming the bump electrodes 2 on the wafer 10.

The resin film adhering equipment 30 tentatively adheres the resin film 3 on the wafer 10 as shown in FIG. 4B. FIG. 7 is a sectional view of the resin film 3 using at the mounting apparatus of the present invention. As shown in FIG. 7, the resin film 3 consists of a main film 3a, cover films 3b and 3c that are adhered to the both upper and lower surfaces of the main film 3a.

First, the resin film adhering equipment 30 peels the cover film 3c off the resin film 3, and puts the resin film 3 on the wafer 10 in a state that the surface peeled the cover film 3c of the resin film 3 faces the wafer 10. Next, in order to give adhering strength between the wafer 10 and the resin film 3, the resin film adhering equipment 30 applies heat to the resin film 3 tentatively in a vacuum and tentatively adheres the resin film 3 to the wafer 10.

FIG. 8 is a sectional view showing a first structure of a resin film tentative adhering instrument in the resin film adhering equipment 30 of the mounting apparatus of the present invention. This instrument utilizes a vacuum laminating method. In FIG. 8, the wafer 10 adhered the resin film 3 whose cover film 3c was peeled is put on a stage 32. The stage 32 provides a heater 34. And a heat resist film 31 covers the stage 32 in a state that the heat resist film 31 covers the wafer 10 adhered the resin film 3. A vacuum pump 33 connects to a through hole provided at the stage 32.

At the state shown in FIG. 8, the air inside the space covered by the heat resist film 31 on the stage 32 is let out by operating the vacuum pump 33, and the space becomes nearly a vacuum state. Consequently, the heat resist film 31 shrinks, and the resin film 3 is pushed to the wafer 10 from above. At the same time of the reducing atmospheric pressure, the resin film 3 is tentatively heated through the wafer 10 by operating the heater 34. The condition of reducing the atmospheric pressure is not limited to the state mentioned above, if bubbles existing between the resin film 3 and the wafer 10 can be removed. At the case that the bubbles remain, some bonding troubles may occur when the bare chip 1 is mounted on the mounting substrate 4. At the present invention, the atmosphere is reduced to about 5 torr. And at the heating executing by the heater 34 at the same time of the reducing atmospheric pressure, the tentative heating condition is that the heating time is about 3 minutes at 80° C. This tentative heating condition is also not limited, it is enough that the resin film 3 can contact closely with the wafer 10, that is, it is enough that only the surface of the resin film 3 is melted or about 20% of the resin film 3 is melted.

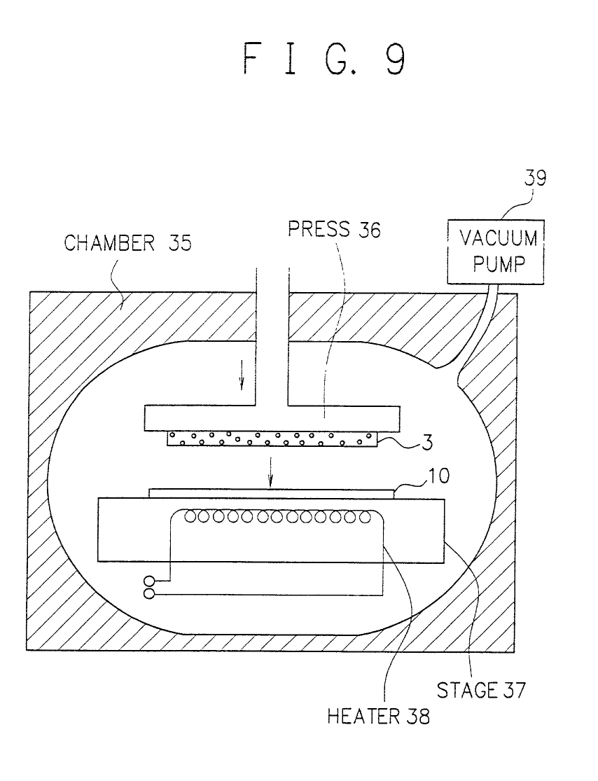

FIG. 9 is a sectional view showing a second structure of a resin film tentative adhering instrument in the resin film adhering equipment 30 of the mounting apparatus of the present invention. In FIG. 9, a stage 37 on which the wafer 10 is put, and a press 36 that presses the resin film 3 to the wafer 10, are sealed in a chamber 35. The stage 37 provides a heater 38 in it, and the chamber 35 is connected to a vacuum pump 39.

At the resin film tentative adhering instrument in FIG. 9, first, the press 36 goes down and pushes the resin film 3 to the wafer 10, and at this state, the vacuum pump 39 reduces the atmosphere to about 5 torr. And under reducing the atmosphere, the heater 38 heats the resin film 3 for about 5 minutes at 80° C.

At the resin film tentative adhering instruments shown in FIGS. 8 and 9, in addition to reducing the atmosphere, pressure is applied to the wafer 10 from the resin film 3. Therefore, the adhering strength between the resin film 3 and the wafer 10 can be increased, and the time applying heat can be reduced. And the bubbles can be let out effectively by reducing atmosphere and applying pressure at the same time.

By using some suitable material as the resin film 3, the tentative adhering is completed only by reducing the atmosphere, and the tentative heating by the heater is not needed.

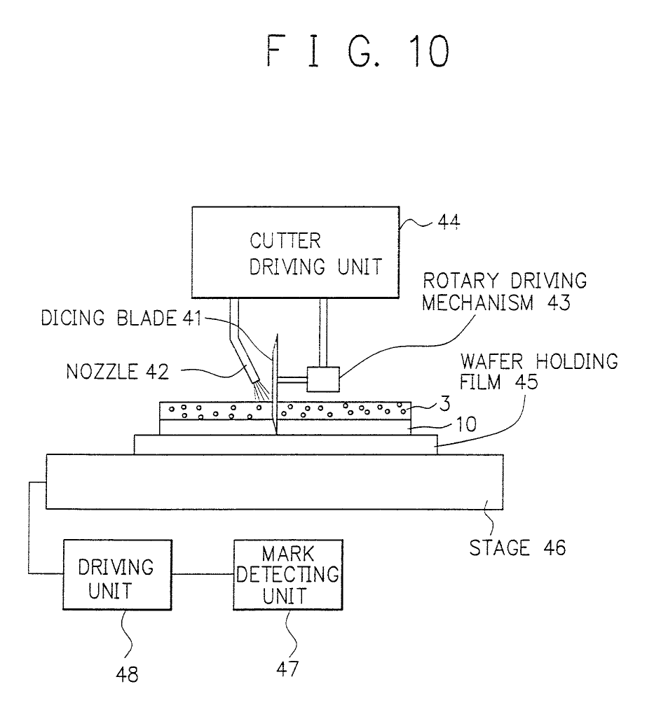

The dicing equipment 40 in FIG. 6 divides the wafer 10 into the bare chips 1. As the dividing method, an existing dicing method can be used. FIG. 10 is a sectional view showing a structure of the dicing equipment 40 in the mounting apparatus of the present invention. In FIG. 10, the wafer 10 tentatively adhered the resin film 3 is put on a wafer holding film 45. The wafer holding film 45 is fixed on a stage 46, and holds the wafer 10 by adhesive strength so that the wafer 10 does not move while the wafer 10 is divided into the bare chips 1 by the dicing used a dicing blade 41. In this, before the dicing, the other cover film 3b shown in FIG. 7 is peeled off. A cutter driving unit 44 provides the dicing blade 41, a rotary driving mechanism 43 for rotating the dicing blade 41, and a nozzle 42 for supplying water to the dicing part.

Positioning the dicing blade 41 before dicing is executed by that a mark detecting unit 47 detects the marks 11 in FIG. 4A. At this time, a driving unit 48 moves the stage 46 and decides the dicing starting position for the dicing blade 41, based on the output from the mark detecting unit 47.

When the dicing is executed for the wafer 10, the dicing blade 41 is moved along the boundaries 12 in FIG. 4A, or at the same time the stage 46 can be moved with the dicing blade 41.

The mounting equipment 50 shown in FIG. 6 executes the processes shown in FIGS. 5B to 5D. Actually, the mounting equipment 50 provides the pressure and heat applying tool 6 shown in FIGS. 5B to 5D and a positioning mechanism for mounting the bare chips 1 divided at the dicing equipment 40 on the mounting substrate 4. As shown in FIGS. 5A to 5C, the positions of the bump electrodes 2 of the bare chip 1 and the pads 5 of the mounting substrate 4 are met, and the bare chip 1 is mounted on the mounting substrate 4. And at this state, as shown in FIG. 5D, the pressure and heat applying tool 6 applies heat and pressure from the side contacting with the bare chip 1.

The conditions applying heat and pressure are decided by the characteristics of the resin film 3. However, at the embodiment of the present invention, the temperature condition is decided to be 100° C., 5 seconds, and 250° C., 5 seconds, that is, total time is 10 seconds. And the pressure is decided to be a constant value 30 g/bump. By using these conditions, the resin film 3 is melted and closely contacts with the mounting substrate 4. After the bump electrodes 2 of the bare chip 1 contacted with the pads 5 of the mounting substrate 4, the resin film 3 is hardened by applying heat from the side contacting with the bare chip 1. With this state, the bump electrodes 2 of the bare chip 1 and the pads 5 of the mounting substrate 4 are connected electrically through the conductive particles in the resin film 3. With the processes mentioned above, the first structure mounted the bare chip 1 on the mounting substrate 4 shown in FIG. 2 is obtained.

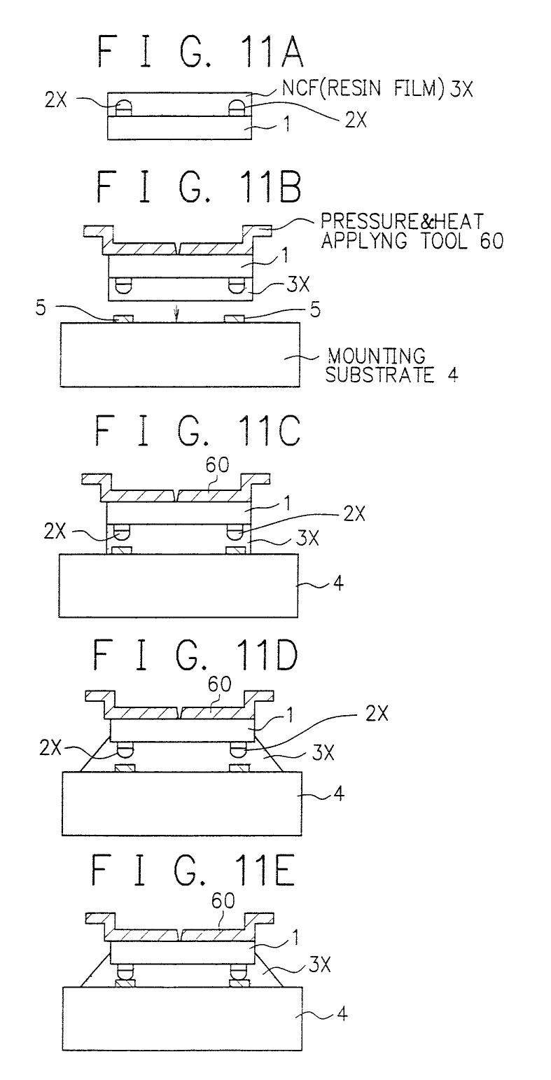

Next, processes to form the second structure shown in FIG. 3 are explained. FIGS. 11A to 11E are sectional views showing the processes at the second structure of the mounting method of the present invention shown in FIG. 3. At this second structure, the same mounting apparatus used at the first structure shown in FIG. 6 is used.

At the second structure, there are processes from forming bump electrodes 2X on the plural bare chips 1 on the wafer 10 to dividing the wafer 10 into each of the bare chips 1 by dicing as shown in FIGS. 4A to 4C. However, at the second structure, the resin film is an NCF 3X and does not contain conductive particles. And each of the bump electrodes 2X formed on the wafer 10 does not have a flat surface, and has a protruded shape.

A bump electrode having a protruded shape can not be formed by a plating method or a vapor deposition method. Therefore, at a method, after mounting a metal ball on a position where the bump electrode is formed, the position is melted, and the bump electrode having the protruded shape is formed. For example, in order to form the bump electrodes, there is a method that metal balls are mounted on the wafer at the same time. At this method, a jig absorbs metal balls at the same positions where the bump electrodes of each of the bare chips are formed, and mounts the absorbed metal balls on the positions where the bump electrodes of each of the bare chips are formed at the same time. After the metal balls are mounted, heat is applied, and the bump electrodes having the protruded shape are formed. This method is an application of an existing method in which bump electrodes are formed on one bare chip, and at this method, the bump electrodes are formed on plural bare chips on the wafer at the same time.

First, as shown in FIG. 11A, the bare chip 1 having the resin film 3X is formed by the dicing process. And the bare chip 1 having the resin film 3X divided by the dicing process is mounted on the mounting substrate 1 by the processes shown in FIGS. 11B to 11E.

These processes are explained. As shown in FIG. 11B, the bare chip 1 having the resin film 3X is held by a pressure and heat applying tool 60, and positioned in a state that the bump electrodes 2X of the bare chip 1 and the pads 5 of the mounting substrate 4 face each other.

After finished the positioning, as shown in FIG. 11C, the pressure and heat applying tool 60 is moved downward, and the resin film 3X is contacted with the mounting substrate 4. After this, as shown in FIGS. 11D and 11E, the bump electrodes 2X of the bare chip 1 penetrate through the resin film 3X and reach the pads 5 of the mounting substrate 4. At this state, the resin film 3X is liquidized by applying heat, and the tips of the bump electrodes 2X of the bare chip 1 are deformed by the pressure applying continuously. With this, the resin film 3X between the bump electrodes 2X and the pads 5 is removed and the bump electrodes 2X and the pads 5 are connected electrically. And by that the resin film 3 is liquidized by applying heat, voids are removed, and also a fillet is formed at the surrounding part of the bare chip 1. And the mounting structure shown in FIG. 3 is completed.

The pressure applying at the second structure shown in FIGS. 11D and 11E is larger than that at the first structure shown in FIGS. 5C and 5D.

At the case that plural bare chips being different sizes are mounted on a mounting substrate, first, each of plural bare chips being different sizes having resin films of different sizes is formed by the processes shown in FIGS. 4A to 4C. And after this, each of the plural bare chips is mounted on the mounting substrate by positioning each of the bare chips and by applying pressure and heat as shown in FIGS. 11B to 11E.

According to the present invention, first, bump electrodes are formed on each of bare chips, at a state that the bare chips are formed on a wafer. And after this, a resin film is adhered to the wafer, and this wafer is divided into each of the bare chips. Therefore, not as the conventional method, it is not necessary to prepare each size of resin film matching to each size of the bare chip, and to supply each size of the resin film to a mounting substrate. Consequently, the mounting cost can be largely reduced.

Second, the size of an ACF being a resin film adhering to the bare chips is enough to the size of the wafer, and it is not necessary to prepare different sizes of the ACF to meet the sizes of the bare chips. Therefore, the waste of the ACF does not occur, and the mounting cost can be largely reduced.

Third, when the resin film is tentatively adhered to the wafer at resin film adhering equipment, the atmosphere is reduced and heat is applied. Therefore, forming bubbles between the bare chip and the resin film can be suppressed, and the reliability can be improved.

As mentioned above, according to the present invention, bump electrodes of each of bare chips are formed on a wafer in which the bare chips are formed at the same time. And a resin film is tentatively adhered to the surface, where the bump electrodes of each of the bare chips are formed, of the wafer. After this, the wafer is divided into each bare chip. And each of the bare chips having the resin film is mounted on a mounting substrate, and bump electrodes of each of the bare chips and pads of the mounting substrate are connected electrically. Therefore, not as the conventional method, it is not necessary to prepare each size of the resin films matching to each size of the bare chips and to supply the different sizes of the resin films on a mounting substrate. Consequently, the mounting cost can be reduced largely.

Furthermore, the size of an ACF being a resin film is enough to be a uniform size to meet the size of the wafer, not depending on the different sizes of the bare chips. Therefore, the waste of the ACF does not occur, and the mounting cost can be reduced largely.

While the present invention has been described with reference to the particular illustrative embodiments, it is not to be restricted by those embodiments but only by the appended claims. It is to be appreciated that those skilled in the art can change or modify the embodiments without departing from the scope and spirit of the present invention.

What is claimed is:

1. A mounting method of bare chips to a mounting substrate, in which bump electrodes of each of said bare chips are connected electrically to pads of said mounting substrate via a resin film put between each of said bare chips and said mounting substrate, comprising the steps of:
forming bump electrodes of plural bare chips on a wafer in which said plural bare chips were formed at the same time;
adhering a resin film on the surface where said bump electrodes were formed on said wafer tentatively;
dividing said wafer into each of said plural bare chips having said resin film by dicing;
mounting each of said plural bare chips having said resin film on said mounting substrate; and
connecting said bump electrodes of each of said plural bare chips to said pads of said mounting substrate electrically by applying heat and pressure.

2. A mounting method of bare chips to a mounting substrate in accordance with claim 1, wherein:
said adhering said resin film on said wafer tentatively is executed under reduced atmospheric pressure.

3. A mounting method of bare chips to a mounting substrate in accordance with claim 1, wherein:
said adhering said resin film on said wafer tentatively is executed under that heat is applied to said resin film at a temperature that said resin film is not hardened, and also under reduced atmospheric pressure.

4. A mounting method of bare chips to a mounting substrate in accordance with claim 2, wherein:
when said reduced atmospheric pressure is applied, pressure pushing said resin film to said wafer is also applied.

5. A mounting method of bare chips to a mounting substrate in accordance with claim 3, wherein:
when said reduced atmospheric pressure is applied, pressure pushing said resin film to said wafer is also applied.

6. A mounting method of bare chips to a mounting substrate in accordance with claim 1, wherein:
said resin film is a thermo-hardening type film and an anisotropic conductive film (ACF) whose hardening contraction coefficient is larger than its thermal expansion coefficient.

7. A mounting method of bare chips to a mounting substrate in accordance with claim 1, wherein:
said resin film is a thermo-hardening type film and a non-conductive film (NCF) whose hardening contraction coefficient is larger than its thermal expansion coefficient.

8. A mounting apparatus of bare chips to a mounting substrate, in which bump electrodes of each of said bare chips are connected electrically to pads of said mounting substrate via a resin film put between each of said bare chips and said mounting substrate, comprising;
bump forming equipment for forming bump electrodes of plural bare chips formed on a wafer at the same time;
resin film adhering equipment for tentatively adhering said resin film on the surface, where said bump electrodes of said plural bare chips were formed, of said wafer;
dicing equipment for dividing said wafer into each of said plural bare chips having said resin film; and
mounting equipment for mounting said each of said plural bare chips having said resin film on said mounting substrate and for connecting said bump electrodes of each of said plural bare chips to said pads of said mounting substrate by applying heat and pressure.

9. A mounting apparatus of bare chips to a mounting substrate in accordance with claim 8, wherein:
said resin film adhering equipment adheres said resin film on said wafer tentatively under reduced atmospheric pressure.

10. A mounting apparatus of bare chips to a mounting substrate in accordance with claim 8, wherein:
said resin film adhering equipment adheres said resin film on said wafer tentatively under that heat is applied to said resin film at a temperature that said resin film is not hardened, and also under reduced atmospheric pressure.

11. A mounting apparatus of bare chips to a mounting substrate in accordance with claim 9, wherein:
said resin film adhering equipment also applies pressure pushing said resin film to said wafer when said reduced atmospheric pressure is applied.

12. A mounting apparatus of bare chips to a mounting substrate in accordance with claim 10, wherein:
said resin film adhering equipment also applies pressure pushing said resin film to said wafer when said reduced atmospheric pressure is applied.

13. A mounting apparatus of bare chips to a mounting substrate in accordance with claim 8, wherein:
said resin film is a thermo-hardening type film and also a resin film whose hardening contraction coefficient is larger than its thermal expansion coefficient.
